(19) United States
(12) Patent Application Publication
(10) Pub. No.: US 2003/0230816 A1
(43) Pub. Date: Dec. 18, 2003

(54) Optically active structure for secured documents and the like, and methods for their production

(75) Inventors: Frank Kappe, Rheda-Wiedenbruck (DE); Manfred Paeschke, Basdorf (DE); Hermann Hecker, Berlin (DE); Gerhard Hochenbleicher, Furstenfeldbruck (DE); Ernst-Bernhard Kley, Jena (DE); Karsten Zollner, Gunzburg (DE)

Correspondence Address: DARBY & DARBY P.C., P. O. BOX 5257, NEW YORK, NY, 10150-5257, US

(73) Assignee: Bundesdruckerei GmbH

(21) Appl. No.: 10/352,371

(22) Filed: Jan. 27, 2003

Related U.S. Application Data
(63) Continuation of application No. PCT/EP01/08352, filed on Jul. 19, 2001.

(30) Foreign Application Priority Data
Jul. 27, 2000 (DE) 100 36 505.1

(51) Int. Cl. H01L 23/58

(52) U.S. Cl. 257/922

(57) ABSTRACT

A secured document contains at least two sets of information on an information layer, the sets of information providing different informational contents when the data carrier is viewed from different angles. The document contains an optically active microstructure having at least two different regions which are transparent, wherein one region has a diffraction structure and the other region is free of diffraction structures. The sets of information which are to be read are disposed in regions beneath the microstructure. The microstructure may comprise a hologram-like sheet in which a grid-like diffraction structure is embossed by means of an embossing punch.

This is a continuation of International Patent Application No. PCT/EP01/08352, filed Jul. 19, 2001 and claims the benefit of German Patent Application No. 100 36 505.1, filed Jul. 27, 2000. The International application was published in German on Feb. 7, 2002, publication No. WO 02/11063 under PCT article No. 21(2).

This invention relates to personalized documents which are extremely difficult to forge or counterfeit and their methods of production.

### BACKGROUND OF THE INVENTION

There are many different types of documents and things which are subject to counterfeiting or forgery, and many different techniques and devices have been developed for determining the authenticity of a document or thing. By way of example only, such documents include bank notes, identification papers, passports, drivers licenses, visas, admission tickets and stock certificates. As used herein, the term “secured document” includes any document or thing which is provided with a distinguishing authenticity element (whether printed or not) which can be used to authenticate, identify or classify the document. The term “authentication element” is intended to refer to any “device” which may be printed on, or otherwise attached to, a secured document for the purpose of authenticating the document or for the purpose of determining its value and/or type or any other characteristic. Likewise, “authenticity” is meant to encompass value, type or other characteristic of a secured document as well as the genuineness of the document.

For personalizing secured documents, laser engraving is frequently used because it provides good protection against forgery; moreover various methods have been proposed for enhancing the protection.

European patents EP 0 216 947 and EP 0 219 012 propose, for example, that the laser inscription be provided by a lenticular screen. In this way the lasered information is visible only at the angle at which it was inscribed. If different directions are used, the lasered information is only visible in those directions.

It is a disadvantage of such systems that, due to the use of an impressed lenticular screen, only thick card bodies can be used. This is because the lenticular screen thickness ranges from 100 to 500 μm and a correspondingly large impression, in the order of 100 μm, results from the use of the screen. In addition, the laser beam is focused through the lens. The lasered information accordingly appears at a depth of a few hundred μm. In the thin card construction used, for example, for passport documents in book form, such a distinguishing authentication element cannot be used.

Moreover, ISO 7810 cards are also excluded if they are to be provided with a chip module. The cavity required by such a chip module usually has a depth of about 400 to 600 μm. However, since the distinguishing authentication element requires layers having a thickness of a few hundred μm, the chip module would be visible from the rear of the card.

It is a further disadvantage that the cards must be tilted during the laser inscription in order to achieve the optically variable effect. Tilting of the card is meaningful, however, only in one of the two vertical and horizontal directions of the card. As a result, the optically variable effect is only possible in one of the two directions.

It is an object of the present invention to produce such optical authentication elements more easily, more readably and also for thin card configurations.

It is also an object of the invention to provide a personalized secured document which has improved protection against forgery.

### SUMMARY OF THE INVENTION

In accordance with the invention, two different sets of information can be read independently of one another at different viewing angles. This is achieved by an optical microstructure which consists of strip-shaped regions which are essentially parallel to one another and either straight or curved. These regions may have approximately the same width and are disposed alternatively, approximately in one plane. Both regions are transparent; however, one region has a diffraction structure, which preferably is constructed as a grid structure.

The diffraction structure is constructed so that the visual axis of the human eye striking it is deflected laterally. Therefore, the information set which is laterally offset next to the diffraction structure is imaged exclusively. This same information is also visible directly through the other region in which there are no diffraction structures. In this case, the information set disposed under the diffraction free region becomes visible simultaneously by looking directly thorough this region, as well as by looking through the diffracting region. The result is optimally readable information which can be read well over a particular range of angles. At angles deviating from this range, the information can no longer be recognized but the information set which is disposed directly under the region provided with the diffraction structure becomes visible. This information can then be read through the diffraction free region as well as through the diffraction region.

Hence, both sets of information can be recognized under different viewing angles through both regions. The information on the information layer may be in black and white or color.

Aside from the production and use of such a diffraction structure for the purpose of separately reading dual information on an information layer, the production and use of so-called volume transmission holograms is also contemplated by the invention. In order to produce such a diffraction structure, two beam fronts are caused to interfere in a light-sensitive layer.

The invention is not limited to laser inscription of a paper substrate. Instead, all printing and inscription methods for producing and/or inscribing an information layer are contemplated by the invention. The optically variable information, for example, may be printed on a paper substrate and subsequently covered by the optical structure of the invention.

Moreover, the invention is not limited to reading dual information from the information layer. The separate reading of more than two sets of information is also contemplated. In that case, there are more than two viewing angles on the microstructure.

### THE DRAWINGS

In the following, the invention is described in greater detail by means of drawings representing several embodiments. Further, inventive distinguishing features and advantages of the invention arise out of the description and the drawings, in which

FIG. 1 is a sectional view of an optical microstructure in accordance with the invention;

FIG. 2 shows an enlarged sectional view of FIG. 1;

FIG. 3 shows a section through a card construction using the microstructure;

FIGS. 4a to 4d show representations of different possibilities for producing micro-structured sheets;

FIGS. 5a to 5c show further possibilities for producing micro-structured sheets;

FIG. 6 shows a plan view of a microstructure in a first embodiment;

FIG. 7 shows a plan view of a microstructure of a second embodiment;

FIG. 8 shows a section through a microstructure of a type, modified from that of FIG. 1;

FIG. 9 shows a section through a further modification of the microstructure;

FIG. 10 shows a section through a further embodiment of a microstructure using a volume hologram;

FIG. 11 shows a section through a version, modified from that of FIG. 10; and

FIGS. 12a-c show representations of different readable sets of information in plan view on the microstructure.

### DETAILED DESCRIPTION OF THE INVENTION

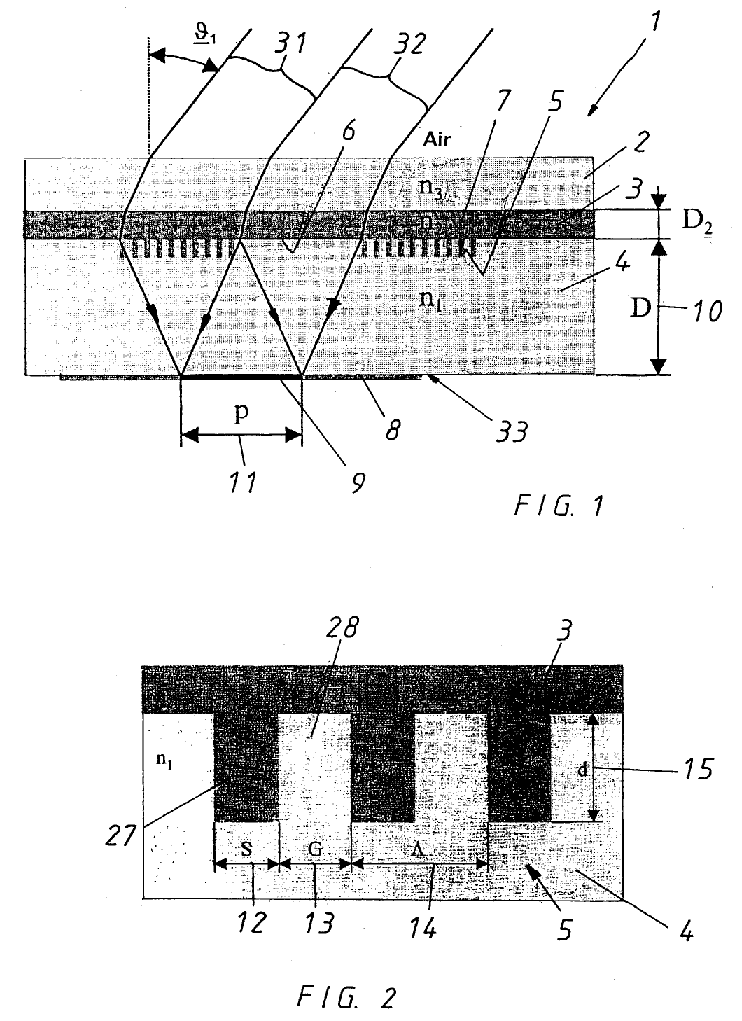

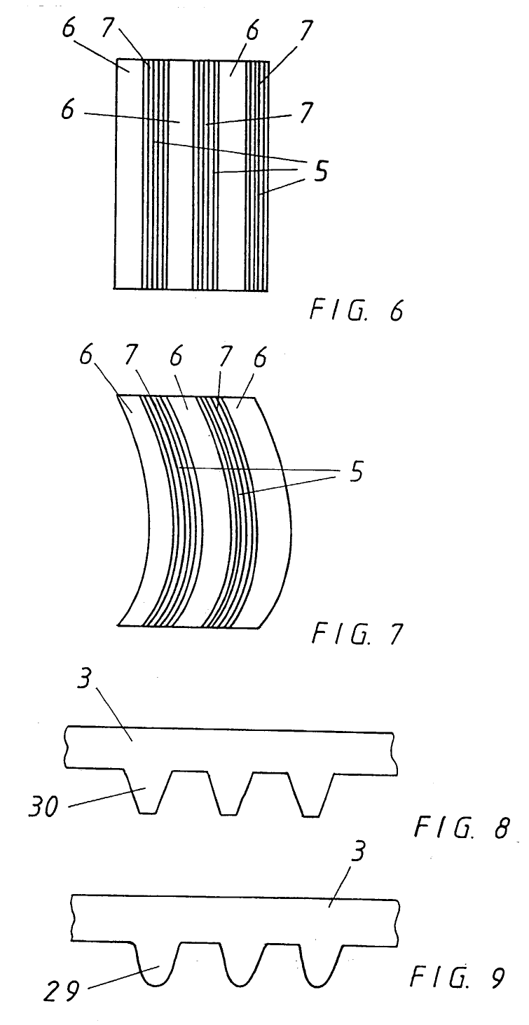

A card 1 according to one embodiment of the invention is shown in section in FIG. 1. The card includes three layers 2, 3 and 4, with the layer 3 containing an optical microstructure comprising strip-shaped regions 6 and 7, disposed approximately parallel to one another, to form a grid-like structure in plan view (FIGS. 6 and 7). The width of the two regions 6 and 7 may be approximately the same. Slight differences in the width can be tolerated and do not significantly affect the readability of the sets of information disposed in the regions 8 and 9 below. It is possible to read these sets of information separately from one another at different viewing angles. They are, for example, burned into a carrier or incorporated or applied in a different form. This layer is referred to generally in the following as information layer 33. Any supporting material which can carry the readable sets of information in the regions 8 and 9, can be used as a carrier material. The uppermost layer 2 has the refractive index n₃. The layer 3, which forms the grid structure 5 at the upper side and/or the lower side, has the refractive index n₂, and the layer 4 below has the refractive index n₁. Beneath this, the information layer 33 is disposed with the two readable sets of information 8 and 9 on its upper surface.

In a particularly preferred embodiment, the material of the information layer 33 consists of PVC, PC, ABS or PET. Aside from the blackening of this material by laser radiation, the colored, laser-induced inscription of a carrier material is also possible as described, for example, in European patent EP 0 828 613 B1. Likewise, all other known printing and application methods are possible.

The, strip-shaped region 6 is highly transparent, while the other strip-shaped region 7 carries a diffraction structure, which preferably is constructed as a grid 5. On looking through diffraction region 7, there are diffraction phenomena which ensure that the region 9, about half of which is offset to region 7, becomes visible. The diffraction structure 5 may be on either or both side(s) of the diffraction region 7.

If the optical microstructure is viewed at the angle θ₁, light passing through the diffraction free region 6 is refracted at the boundaries of the various layers (air to n₃, n₃ to n₂, n₂ to n₁) to the image region 8 (shown in gray in FIG. 1). Light passing through diffraction region 7 is refracted and diffracted (by grid structure 5) to the same image region 8. The width of the grid structure 5 is shown as “p”.

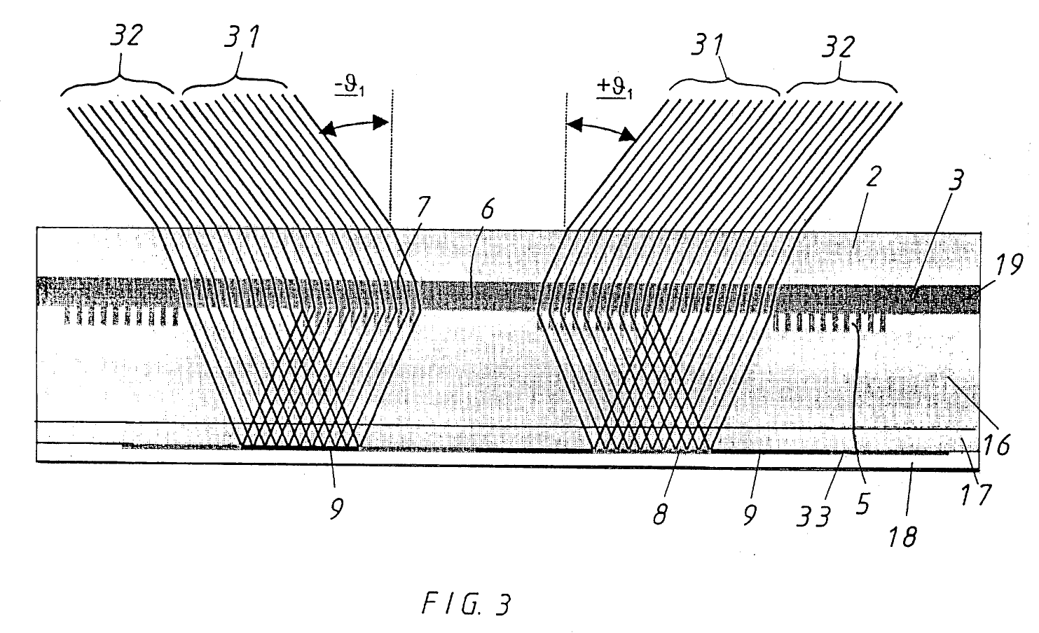

FIG. 3 shows two parallel beams of light 31 and 32 passing through the diffusion free region 6 and the diffusion elements 5 at angles −θ₁, and +θ₁. At −θ₁, the beam 32 is refracted to the image region 9 and the beam 31 is refracted and diffracted to the image area 9. As shown in FIG. 3, the rays entering at an angle of +θ₁ are similarly directed to the image region 8. Thus, for an observer at an angle of −θ₁, the image region 8 is not visible but the image region 9 appears larger than its actual width. From the angle +η₁, region 9 is not visible but region 8 appears larger than its actual width.

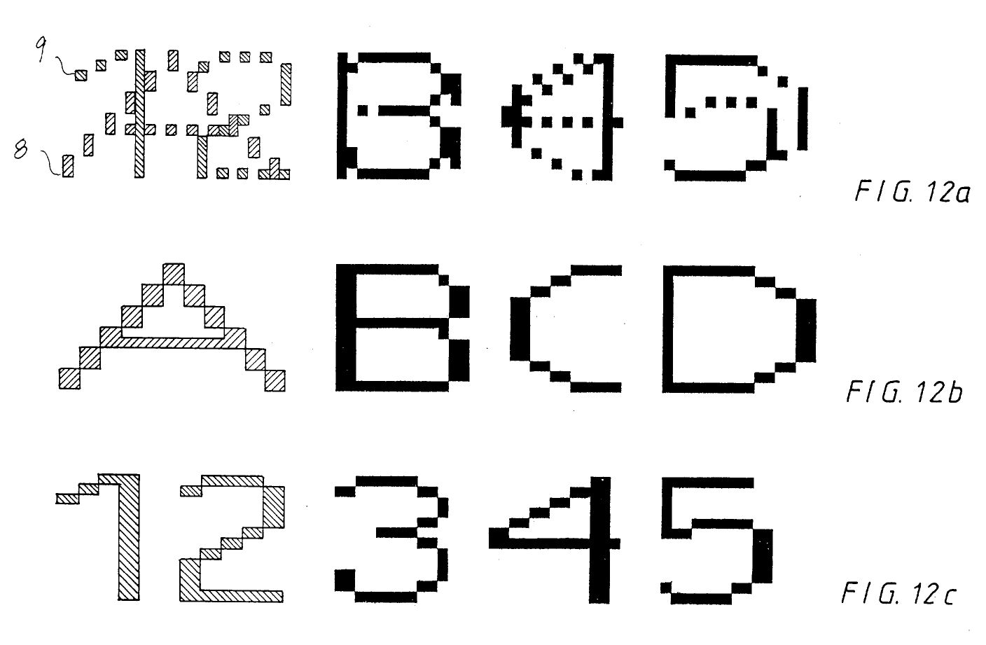

The foregoing effect is illustrated in FIGS. 12a, 12b and 12c. FIG. 12a shows the actual information regions 8 and 9, with part of the information shaded so as to distinguish the two regions. FIG. 12b shows the image observed by the user at the angle −θ₁ and FIG. 12c shows the image observed by the user at the angle +θ₁.

The displacement between the grid 5 and the information layer 33 is p/2. The layer with the refractive index n₂ is optional and can also be omitted. Its primary function is to smooth the surface of the microstructure; it also removes poor sites in the transmission spectrum. The thickness 10 of the layer 4 can also approach zero, and layer 4 can be omitted completely.

The parameters for the optically active structure are shown in FIG. 2. The invention also contemplates the use of a binary grid here.

The design parameters for the diffraction grid arise out of the refractive indices n₁ and n₂ and the geometric grid sizes, such as the grid period 14 (Λ), cross-member width 12 (S), cross-member distance G and grid depth d. As a further design parameter, the distance 10 between the optically active microstructure 5 and the lasered information (in the region 8) must be given (see Table 1 below).

Some possible examples for the grid structure parameters according to the invention are given in Table 1 below. All of the values in the table and the properties resulting therefrom are within the scope of the invention.

TABLE 1
Examples of the Design Parameters for the Microstructure with n1 = n₃

| # | Parameter | | Design 1 | Design 2 | Design 3 |
|---|---|---|---|---|---|
| 10 | Layer thickness | D (μm) | 250 | 250 | 1500 |
| | with n₁ | | | | |
| 11 | Pixel size | p (μm) | 113.7 | 90.0 | 555.6 |
| | Incident/ | In air | ±19.42 | ±15.43 | ±15.43 |
| | emergence angle | (grd) | | | |
| | | In n₂ | ±12.81 | 10.21 | ±15.43 |
| | | (grd) | | | |
| 4 | Refractive index | n₁ | 1.5 | 1.5 | 1.0 |
| 3 | | n₂ | 1.9 | 1.0 | 1.46 |
| 14 | Grid period | A (nm) | 800 | 1000 | 1000 |
| 12 | Cross-member | S (nm) | 200 | 800 | 200 |
| | width (n₂) | | | | |
| 15 | Grid height | d (nm) | 1080 | 1060 | 1045 |
| 7 | Efficiency | TE (%) | 89.29 | 71.64 | 86.20 |
| | of the grid | TM (%) | 88.0 | 87.84 | 80.46 |
| | | Ø (%) | 88.64 | 79.74 | 83.33 |
| 6 | Efficiency of | (%) | 98.62 | 100.00 | 96.49 |
| | the diffraction - | | | | |
| | free regions | | | | |
| | Total efficiency | (%) | 93.63 | 89.87 | 89.91 |

The efficiency is listed in the last line of the table above. It indicates how much of the (for example, lasered) information can be seen at the viewing angle θ₀. The values for TE polarized light as well as for TM polarized light are given. For the diffraction free regions 6, only the Fresnel losses by reflection at the interfaces are taken into consideration. On the other hand, the diffraction region 7 also takes the efficiency of the diffraction into consideration.

For the case presented here, the efficiency of the structure as a whole is preferably designed so that it is about 90% or higher.

The card construction I is shown diagrammatically in FIG. 3. The card is constructed from sheets 16, 17 and 18, which have different properties and can be laminated. The sheets differ in their transparency and in their ability to be marked by laser radiation. Pursuant to the invention, the optical effect is achieved by a hologram-like micro structured sheet 19, which, after the laser personalization process, is applied on the card body consisting of the sheets 16, 17 and 18. This process is preferred because the card 1 need not be tilted during the personalization. It is also within the scope of the invention that tilting take place during personalization and/or that laser personalization takes place after the sheet 19 is applied.

In the event that a hologram-like sheet 19 is used, the latter can be transferred to the card body of sheets 16, 17 and 18 by means of a conventional hot embossing device.

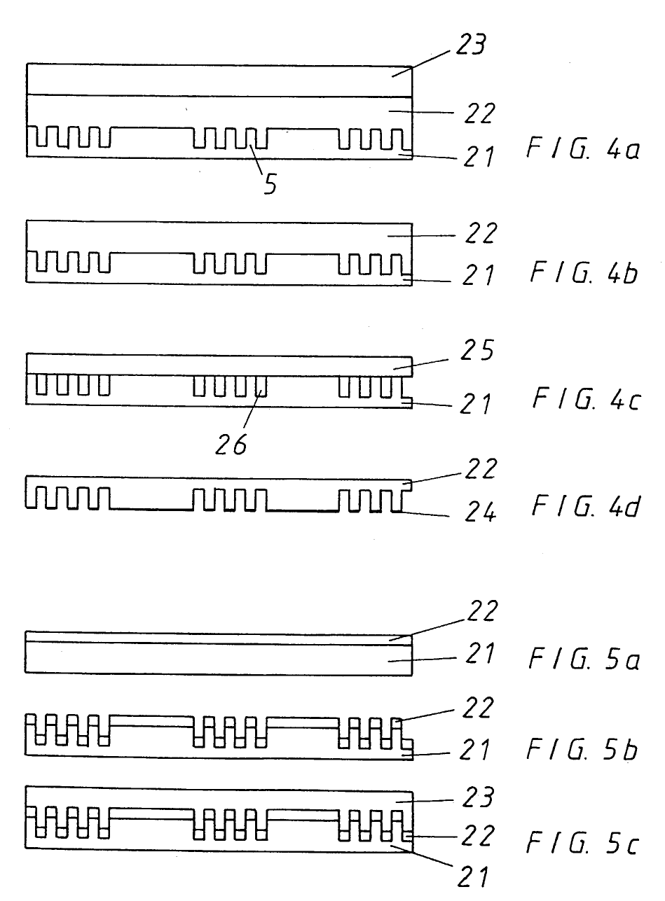

There are different ways for producing the hologram-like sheet 19 and they are described with reference to FIGS. 4 and 5. For producing the layers shown in FIG. 4, as well as for producing conventional hologram sheets, it is necessary to prepare an embossing punch. This embossing punch may be produced, for example, by transferring a mask, prepared by electron beam exposure, onto a nickel substrate. This nickel substrate is subsequently used as a punch for embossing the sheet 19 or the embossing lacquer used in its place.

For producing the layer structure shown in FIG. 4a, initially the binary grid 5 is embossed into the material 21 by means of the punch mentioned above. The material 21 may consist of a sheet or a lacquer which can be cured, for example, by means of ultra violet light. Usually this material has a low refractive index, for example about 1.5. In a second step (FIG. 4b), the embossing is covered by a layer (material 22) with the refractive index n₂ so that the rifts of the grid structure 5 are filled uniformly and a smooth surface results. Such a leveling is possible by applying a lacquer of low viscosity on the embossed microstructure 5. The narrow, deep rifts should be filled completely with lacquer.

A further possibility of leveling consists of coating the embossed microstructure 5 with a dielectric layer. Such a layer (material 25 of FIG. 4c) can be produced by coating methods such as vapor deposition or sputtering.

In both cases, i.e. with a lacquer or dielectric coating, it is necessary that the refractive index of the covering material be quite different from that of the material with the embossed structure. Usually, the refractive index for the coating material is higher than the refractive index of the material 21 in which the microstructure 5 was embossed.

At the present time, by varying the lacquer, refractive indexes up to a maximum of n₂=2.0 are available. Dielectric materials 25 with a higher refractive index are also available. Zinc sulfide and zirconium oxide, for example, are typical materials.

In order to protect the layers constructed, the layer of material 22 can be provided additionally with a layer of protective material 23 (FIG. 4a). However, it is also possible to do without this layer if material 22 offers sufficient protection against scratching (FIG. 4b).

A different variation of FIG. 4c is obtained if, instead of a lacquer of low viscosity, a lacquer (material 25) is used, which does not penetrate into the narrow rifts of the embossed microstructure 5. In this case, the air, which is in the rifts, is enclosed and sealed by the lacquer. Chambers 26 with the refractive index of n₂=1.0, are formed in the construction shown in FIG. 4c.

It may, however, also be sufficient to provide the layer (material 22) containing the embossed microstructure 5 with an adhesive system 24 in the manner shown in FIG. 4d. The adhesive system may, for example, be a thermoplastic hot-melt-type adhesive or a heat-curing adhesive. The microstructure 5 then does not need a further layer and can be applied directly on the card body.

A further possible layer construction of the hologram-like sheet 19 is shown in FIG. 5. In order to prepare it, the microstructure (FIG. 5b) is transferred into a sheet (FIG. 5a), which is coated with a dielectric layer, with the help of an embossing punch. Subsequently, the microstructure is sealed with a lacquer. Usually, the dielectric layer (material 22) has a refractive index which is higher than that of the material surrounding it. The refractive index of the dielectric layer may, for example, be n₂. The surrounding material 21 or 22 usually has the same refractive index n₁=n₂=1.5.

In contrast to the sheets described above, such a construction of layers has the advantage that the starting sheet can be produced more easily. In general, it is difficult to coat a microstructure 5 which is not flat, and it is difficult to apply a homogeneous leveling material. On the other hand, it is state of the art to provide smooth sheets with a uniform, dielectric layer.

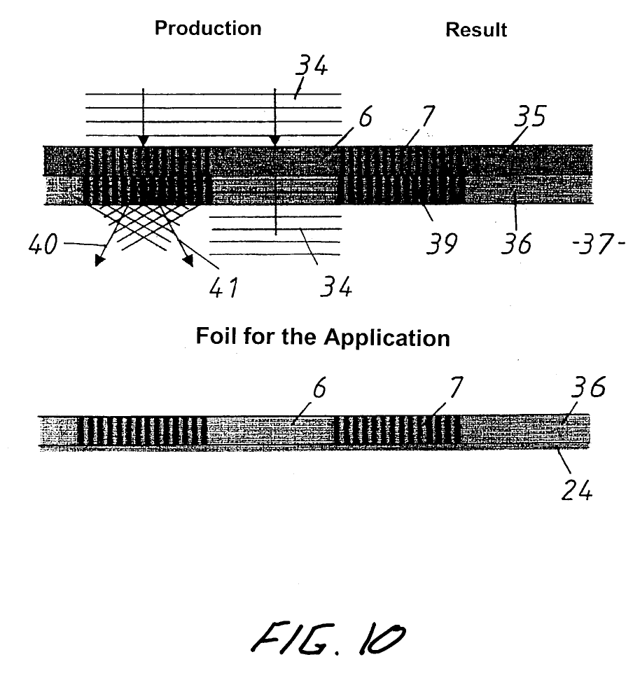

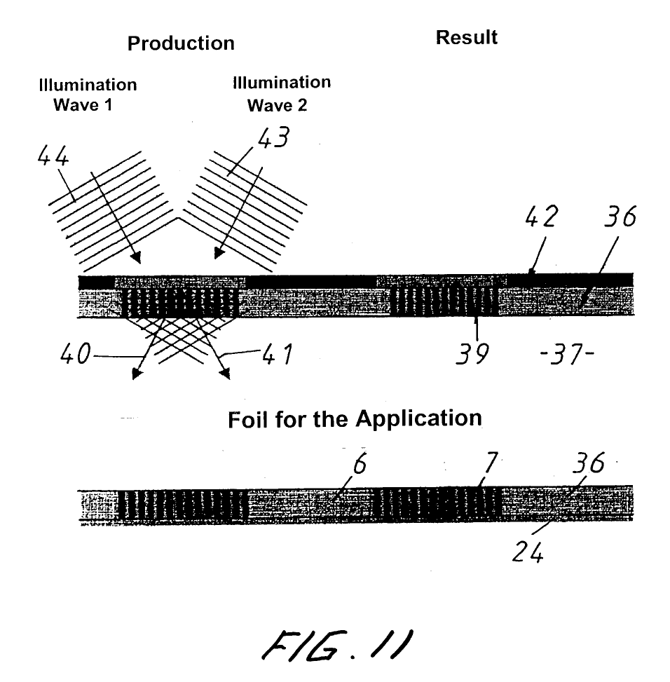

FIGS. 8 and 9 show other possible examples of a grid structure 5 in which the profiles of the cross-member elements 30 are not rectangular. A rectangular shape, however, is preferred because of the optimum utilization of the Bragg effect. This effect is most clearly pronounced in the case of a binary rectangular profile.

However, profile forms which deviate from rectangular may also be used for the cross-member element 29 or 30. An approximately trapezoidal cross-member element 30 is shown in FIG. 8 and a half round, elliptical or oval, cross-member element 29 is shown in FIG. 9. As mentioned above, the grid structure need not necessarily be on the underside of the layer 3. It may also be disposed on the upper side of the latter or on both sides.

A further possibility for providing the inventive, hologram-like sheet 19 is shown in FIGS. 10 and 11. In these cases, the sheet 19 is defined by a volume transmission hologram. The methods employed here differ from those used for the preparation for the hologram-like sheet 19 in FIGS. 4a-d) and or 5a-c. The novel sheet has the same optical properties shown in FIGS. 1 and 3.

Volume transmission holograms result when two beams are caused to interfere in a light-sensitive layer. In the light-sensitive layer, the refractive index of the material is altered in the regions of constructive interference. The “holographic recording film” of DuPont is a so-called protopolymer which can be used for this purpose.

One possibility of realizing this is shown in FIG. 10. In this case, the necessary interference patterns are produced by the diffraction of the plane, monochromatic illumination wave at a plasma mask.

A plasma mask changes the phase position of an illumination wave. This is achieved by the difference in optical paths which the illumination wave experiences through such a mask. The optical path through the region of the phase mask, shown in gray, is different from that through the surrounding region of the mask. The optical path is obtained by multiplying the geometrical path through the mask by the refractive index. Accordingly, the optical path difference can be produced by a modulation of the refractive index, by a change in the geometry or by a combination of the two.

In the region of the phase lattice, the illumination wave is diffracted into the 1^{st} or −1^{st} order. Interference between the two wave fronts of the 1^{st} and −1^{st} order comes about in the region of a dichromate gelatin (preferably a photopolymer material). The refractive index pattern, produced by the interference of the wave fronts, is shown in the right part of the Figure. In the region in which there is no phase mask, the illumination wave passes through the photopolymer without forming an interference pattern. In this way, a region 7 with a refractive index modulation and a region 6 without a refractive index modulation result in the photopolymer, as shown in the right part of FIG. 10.

Such a phase mask can be produced by etching a binary lattice in a glass substrate. The path or phase difference for the illumination wave is then produced by the different optical path length through the phase lattice.

A further procedure for realizing the volume transmission hologram is shown in FIG. 11. In this case, two illumination waves intersect at an angle on the photopolymer.

It is a property of this material that its refractive index is changed under the influence of light. An illumination by an interference pattern images this after the development as a modulation of the refractive index. Accordingly, an interference pattern is formed and a corresponding refractive index pattern also results due to this illumination. The regions which are not to have a lattice structure pursuant to the invention are covered by an amplitude mask.

An amplitude mask permits the photopolymer to be illuminated only in the transparent regions (shown in gray in the drawing). In the other regions, the mask is opaque (shown in black in the drawing). Accordingly, regions with and without a refractive index modulation appear in the right part of FIG. 11.

The only difference between a phase mask and an amplitude mask is the way in which it is made. In both cases, the result is almost identical. For the phase mask, only a coherent, illumination wave is required in order to produce the interference pattern. For an amplitude mask, two coherent illumination waves are required. However, it is more complicated to produce a phase mask than an amplitude mask.

Amplitude masks are produced photolithographically or by electron beam illumination. Phase masks can be produced, for example, by etching a binary lattice. The amplitude mask transmits the illumination waves only in the transparent regions. The phase mask diffracts the light in the region of the binary lattice. The diffracted light, so produced, interferes. The transparent and opaque regions of the amplitude lattice and also the regions of the phase mask with and without a phase lattice correspond to the regions 6 and 7 in FIGS. 1 and 3.

In both cases, the volume transmission hologram, so prepared, can also be used as sheet 19. The volume transmission hologram is applied on the information carrier by means of an adhesive system before or after the personalization.

The same size data, given in Table 1, also applies to the order of magnitude of the binary lattice of the phase and amplitude mask.

A support sheet is not shown in FIGS. 10 and 11. Instead, the photopolymer is shown with an adhesive system, which is required in order to apply the sheet to the card body. After the application, the mode of action of the sheet is precisely as shown in FIGS. 1 and 3.

Three or more sets of information can also be disposed on the information layer 33. In this case, the third set of information would be read separately from the two other sets of information of FIGS. 12b and c at a defined, third viewing angle.

List of Reference Numbers

1. card construction

2. layer

3. layer

4. layer

5. grid structure

6. diffraction free region

7. diffraction region

8. information region (gray)

9. information region (black)

10. distance (D) thickness

11. width (p)

12. width of cross-member (S)

13. distance of cross-member (G)

14. lattice period (Λ)

15. lattice depth (d)

16. sheet

17. sheet

18. sheet

19. microstructured sheet

20. material

21. material

22. material

23. material

24. adhesive system

25. material

26. chamber

27. cross section of element

28. interstice

29. cross sectional element

30. cross sectional element

31. beam of light

32. beam of light

33. information layer

34. illumination wave

35. phase mask

36. dichromate gelatin

37. support substance

38. grid structure

39. grid structure

40. wave front

41. wave front

42. amplitude mask

43. illumination wave

44. illumination wave

We claim

1. An optically active microstructure for secured documents wherein at least two sets of information are contained on an information layer (33), the sets of information providing a different informational content when the data carrier is viewed from different angles, wherein the microstructure comprises at least two different regions (6, 7), both of which are transparent, wherein one region (7) has a diffraction structure and the other region (6) is free of diffraction structures, and the sets of information, which are to be read, are disposed in regions (8, 9) beneath the microstructure.

2. The microstructure of claim 1, wherein the diffraction structure is constructed as a grid structure (5).

3. The microstructure of claim 2, wherein the grid structure (5) comprises parallel strip-like elements (27), between which interstices (28) are formed.

4. The microstructure of claim 3, wherein said other region comprises parallel, approximately strip-shaped regions (6).

5. The microstructure of claim 3, wherein the cross section of the strip-like elements (27) is rectangular.

6. The microstructure of claim 3, wherein the cross section of the strip-like elements (29, 30) is either approximately sinusoidal, elliptical, oval or a flattened saw tooth.

7. The microstructure of claim 3, wherein
the grid period (\hat{ }) is between about 800 and 1000 nm;
the width of the strip-like elements (5) is between about 200 and 800 nm; and
the grid height (d) is between about 1045 and 1080 nm.

8. The microstructure of claim 3, wherein the distance between the microstructure and the sets of information (D) is approximately 100 μm and the width of the lasered information (p) about 45.5 μm.

9. A secured document containing at least two sets of information on an information layer (33), the sets of information providing a different informational content when the data carrier is viewed from different angles, comprising an optically active microstructure having at least two different regions (6, 7), both of which are transparent, wherein one region (7) has a diffraction structure and the other region (6) is free of diffraction structures, and wherein the sets of information which are to be read are disposed in regions (8, 9) beneath the microstructure.

10. The secured document of claim 9, wherein the diffraction structure is constructed as a grid structure (5).

11. The secured document of claim 10, wherein the grid structure (5) comprises parallel strip-like elements (27), between which interstices (28) are formed.

12. The secured document of claim 11, wherein said other region comprises parallel, approximately strip-shaped regions (6).

13. The secured document of claim 11, wherein the cross section of the strip-like elements (27) is rectangular.

14. The secured document of claim 11, wherein the cross section of the strip-like elements (29, 30) is either approximately sinusoidal, elliptical, oval or a flattened saw tooth.

15. The secured document of claim 11, wherein
the grid period (\hat{ }) is between about 800 and 1000 nm;
the width of the strip-like elements (5) is between about 200 and 800 nm; and
the grid height (d) is between about 1045 and 1080 nm.

16. The secured document of claim 11, wherein the distance between the microstructure and the sets of information (D) is approximately 100 μm and the width of the lasered information (p) about 45.5 μm.

17. A method for making a microstructure for data carriers of all types for which irreversible changes (sets of information) are inscribed by means of a laser beam in at least one of several superimposed sheets (16 to 18) of the data carrier and the sets of information have a different informational content when the data carrier is viewed from different angles, wherein the microstructure (1) comprises a hologram-like sheet (19) in which a strip-like structure (5) is embossed by means of an embossing punch.

18. The method of claim 16, wherein, after the laser personalization process, the microstructured sheet (19) is applied on the card body.

19. The method of claim 9, wherein the sheet (19) is transferred with a hot embossing device to the card body.

20. The method of claim 17, wherein, in a first step, the lattice structure (5) is embossed by means of the embossing punch in a UV-curable lacquer.

21. The method of claim 19, wherein, in a second step, the lattice structure (5) is covered by a layer (material 22) with the refractive index n₂, so that the interstices (28) of the lattice structure (5) are filled uniformly and a surface, which is as smooth as possible, results.

22. The method of claim 20, wherein a lacquer of low viscosity is applied on the embossed microstructure (5).

23. The method of claim 20, wherein the embossed microstructure (5) is covered by means of a dielectric layer (material 25).

24. The method of claim 21, wherein the refractive index of the covering material is as different as possible from the refractive index of the material with the embossed structure.

25. The method of claim 20, wherein, instead of the lacquer of low viscosity, a lacquer (material 25) is used, which does not penetrate into the narrow interstices (28) of the embossed microstructure (5), and the air in the interstices are enclosed and sealed by the lacquer.

26. The method of claim 17, wherein the tips of the strip-like structure (5) are covered with a hot-melt adhesive, which leaves the interstices (28) between the cross-member elements open.

27. The method of claim 17, wherein, for producing the microstructured sheet (19), the microstructure (FIG. 5b), which subsequently is sealed with a lacquer (FIG. 5c) is transferred with a sheet (FIG. 5a), coated with a dielectric layer, with the help of the embossing punch.

28. A method for producing a microstructure for data carriers of all types, for which, by means of a laser beam, irreversible sets of information are inscribed in at least one of several superimposed sheets (16 to 18) of the data carrier and the sets of information, when the data carrier is viewed from different angles, have a different informational content, wherein the microstructure (1) in the sheet (19) is formed as a volume transmission hologram.

29. The method of claim 28, wherein the microstructure is formed as a thick layer hologram.

30. The method of claim 28, wherein a volume transmission hologram is produced owing to the fact that two beams are caused to interfere in a light-sensitive layer (photopolymer layer) and, by these means, the refractive index of the material is changed in the light-sensitive layer in the regions of the constructive interference.

31. The method of claim 30, wherein the necessary interference pattern is produced by the diffraction of the plane monochromatic illumination wave at a phase mask and, in the region of the phase lattice, the illumination wave is diffracted into the 1^{st} or −1^{st} order and that there is interference between the two wave fronts of the 1^{st} and −1^{st} order in the region of the photopolymer.

32. The method of claim 31, wherein the phase mask is produced by etching a binary lattice in a glass substrate.

33. The method of claim 28, wherein the diffraction pattern of the microstructure is produced by different refractive index modulation in the regions (6, 7).

34. The method of claim 33, wherein a phase mask is used to expose the photopolymer.

35. The method of claim 33, wherein an amplitude mask is used to expose the photopolymer.

36. The method of claim 35, wherein in the amplitude mask is produced by electron beam exposure or by a photolithographic method.
